(19) United States
(12) Patent Application Publication
(10) Pub. No.: US 2007/0029558 A1
(43) Pub. Date: Feb. 8, 2007

(54) Method for manufacturing p-type gallium nitride compound semiconductor, method for activating p-type impurity contained in gallium nitride compound semiconductor, and apparatus for activating p-type impurity contained in gallium nitride compound semiconductor

(75) Inventor: Kazuhiro Nishizono, Seika-cho (JP)

Correspondence Address: DITTHAVONG & MORI, P.C., 10507 BRADDOCK ROAD, SUITE A, FAIRFAX, VA, 22032, US

(73) Assignee: KYOCERA Corporation, Kyoto (JP)

(21) Appl. No.: 11/489,872

(22) Filed: Jul. 20, 2006

(30) Foreign Application Priority Data
Aug. 3, 2005 (JP) 2005-225967

(51) Int. Cl. H01L 33/00

(52) U.S. Cl. 257/96

(57) ABSTRACT

A method for manufacturing a p-type gallium nitride compound semiconductor includes providing a gallium nitride compound semiconductor containing a p-type impurity on a surface of a conductive substrate, immersing in an electrolytic solution the conductive substrate on which the gallium nitride compound semiconductor is provided, providing a cathode to be in contact with the electrolytic solution, and applying a current between the cathode and the conductive substrate serving as an anode to activate the p-type impurity.

### CROSS-REFERENCE TO RELATED APPLICATIONS

The present application claims priority under 35 U.S.C. §119 to Japanese Patent Application No. 2005-225967, filed Aug. 3, 2005, entitled “METHOD FOR MANUFACTURING P-TYPE GALLIUM NITRIDE COMPOUND SEMICONDUCTOR AND GALLIUM NITRIDE COMPOUND SEMICONDUCTOR DEVICE.” The contents of this application are incorporated herein by reference in their entirety.

### BACKGROUND OF THE INVENTION

1. Field of the Invention

The present invention relates to a method for manufacturing a p-type gallium nitride compound semiconductor, a method for activating a p-type impurity contained in a gallium nitride compound semiconductor, and an apparatus for activating a p-type impurity contained in a gallium nitride compound semiconductor.

2. Discussion of the Background

In gallium nitride compounds, such as aluminum gallium nitride (AlₓGa₁₋ₓN), which is a mixed-crystal compound of gallium nitride (GaN) and aluminum nitride (AlN), and indium gallium nitride (InₓGa₁₋ₓN), which is a mixed-crystal compound of gallium nitride (GaN) and indium nitride (InN), by adjusting the coefficient x in the formula of each gallium nitride compound, it is possible to produce light emission at a given wavelength in the range from the visible region to the ultraviolet region. Consequently, research has been conducted on these compounds for practical use as materials for forming light-emitting devices, such as semiconductor light-emitting diodes and semiconductor lasers, which emit blue light or light in the ultraviolet region, in particular. Furthermore, the gallium nitride compounds have been receiving attention as semiconductor materials for high-power, high-frequency field-effect transistors and the like.

In order to put gallium nitride compounds to practical use as materials for forming light-emitting devices, it is necessary to establish a technique for manufacturing low-resistance, high-quality gallium nitride compound semiconductors of p-conductivity type or n-conductivity type. With respect to n-type gallium nitride compound semiconductors, it is possible to relatively easily manufacture low-resistance, high-quality products by adding silicon (Si) or the like as an n-type (donor) impurity to gallium nitride compounds.

However, with respect to p-type gallium nitride compound semiconductors, it is not possible to manufacture products that have low resistance and high quality comparable to the n-type gallium nitride compound semiconductors by simply adding magnesium (Mg), zinc (Zn), or the like as a p-type (acceptor) impurity to gallium nitride compounds. The reason for this is that the activation rate of the p-type impurity is low, which results from the fact that, when the gallium nitride compound semiconductors are formed on conductive substrates, for example, by metalorganic chemical vapor deposition (MOCVD), hydrogen produced from decomposition of ammonia (NH₃), which is used as a source material for nitrogen, easily bonds with the p-type impurity.

Consequently, the manufacture of a low-resistance p-type gallium nitride compound semiconductor by activation by dehydrogenation of a p-type impurity contained in a gallium nitride compound semiconductor has been studied. For example, Japanese Patent No. 2540791 describes a gallium nitride compound semiconductor containing a p-type impurity being annealed by heating at 400° C. or higher in an atmosphere substantially free from hydrogen to dehydrogenate the p-type impurity for activation. The contents of this publication are incorporated by reference in their entirety. Furthermore, Japanese Unexamined Patent Application Publication Nos. 2001-351925 and 2004-14598 each describe a gallium nitride compound semiconductor containing a p-type impurity being placed between RF electrodes and a high-frequency electric field being applied between the electrodes to dehydrogenate the p-type impurity for activation. The contents of these publications are incorporated by reference in their entirety.

### SUMMARY OF THE INVENTION

According to one aspect of the present invention, a method for manufacturing a p-type gallium nitride compound semiconductor includes providing a gallium nitride compound semiconductor containing a p-type impurity on a conductive substrate, immersing in an electrolytic solution the conductive substrate on which the gallium nitride compound semiconductor is provided, providing a cathode to be in contact with the electrolytic solution, and applying a current between the cathode and the conductive substrate serving as an anode to activate the p-type impurity.

According to another aspect of the present invention, a method for activating a p-type impurity contained in a gallium nitride compound semiconductor includes immersing in an electrolytic solution a conductive substrate on which the gallium nitride compound semiconductor containing the p-type impurity is provided, providing a cathode to be in contact with the electrolytic solution, and applying a current between the cathode and the conductive substrate serving as an anode immersed in the electrolytic solution to activate the p-type impurity.

According to further aspect of the present invention, an apparatus for activating a p-type impurity contained in a gallium nitride compound semiconductor includes a container, a cathode, an anode, an electric power source, and a controller. The container is configured to contain an electrolytic solution. The cathode is provided in the container to be in contact with the electrolytic solution. The anode comprises a conductive substrate on which a gallium nitride compound semiconductor containing a p-type impurity is provided and which is to be in contact with the electrolytic solution. The electric power source is configured to apply a current between the anode and the cathode. The controller is configured to control the electric power source to activate the p-type impurity.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic diagram showing an example of a treatment apparatus used in the step of activating a p-type impurity contained in a gallium nitride compound semiconductor in a method for manufacturing a p-type gallium nitride compound semiconductor according to an embodiment of the present invention;

FIG. 2 is a cross-sectional view showing a layer structure of a light-emitting diode as an example of a gallium nitride compound semiconductor device according to an embodiment of the present invention; and

FIG. 3 is a cross-sectional view showing a layer structure of a model of a gallium nitride compound semiconductor device fabricated in Example 1 according to an embodiment of the present invention.

### DESCRIPTION OF THE EMBODIMENTS

The embodiments will now be described with reference to the accompanying drawings, wherein like reference numerals designate corresponding or identical elements throughout the various drawings.

According to an embodiment of the present invention, a method for manufacturing a p-type gallium nitride compound semiconductor includes the steps of forming a gallium nitride compound semiconductor containing a p-type impurity on a conductive substrate, and activating the p-type impurity by applying a current between the conductive substrate serving as an anode and a cathode disposed in contact with the electrolytic solution under the state in which the conductive substrate provided with the gallium nitride compound semiconductor is immersed in an electrolytic solution.

As the conductive substrate, any of various substrates having a resistivity of about 10⁻¹ to 10⁻⁶ Ωcm, for example, composed of gallium oxide (Ga₂O₃), silicon carbide (SiC), gallium nitride (GaN), zirconium diboride (ZrB₂), titanium diboride (TiB₂), or the like may be used. In particular, a conductive substrate composed of a single crystal of zirconium diboride (ZrB₂) is preferable from the standpoint that the conductivity is high at a resistivity of about 10⁻⁶ Ωcm which is comparable to that of a metal, and that the lattice constant matches that of the gallium nitride compound semiconductor and a semiconductor having excellent crystal quality, high light emission efficiency, and the like can be formed thereon by a vapor-phase deposition method or the like. If the conductive substrate is used, it is not necessary to prepare an electrode separately, and by connecting a wire to a surface of the conductive substrate other than the surface on which the gallium nitride compound semiconductor is provided, it is possible to prevent contamination of the semiconductor.

A low-temperature growth buffer layer composed of gallium nitride (GaN), aluminum nitride (AlN), or the like may be disposed on the surface of the conductive substrate in order to further enhance the crystal quality of the gallium nitride compound semiconductor. Furthermore, a dislocation reduction technique, such as a lateral growth technique or a facet-controlled growth technique, may be employed.

As the method for forming a gallium nitride compound semiconductor containing a p-type impurity on a conductive substrate, a vapor-phase deposition method, such as metalorganic chemical vapor deposition (MOCVD), is preferably used. That is, while maintaining the conductive substrate at a predetermined temperature, source gases for a gallium nitride compound and a p-type impurity are introduced to allow chemical reactions to occur on a base for forming the gallium nitride compound semiconductor on the substrate, and a gallium nitride compound having a predetermined composition and a p-type impurity are deposited. Thereby, a gallium nitride compound semiconductor containing the p-type impurity is formed. As the vapor-phase deposition method, for example, molecular beam epitaxy (MBE), hydride vapor phase epitaxy (HVPE), or the like may also be employed.

Examples of the gallium nitride compound semiconductor containing the p-type impurity include gallium nitride (GaN), aluminum gallium nitride (AlₓGa₁₋ₓN), and indium gallium nitride (InₓGa₁₋ₓN). Examples of the p-type impurity include magnesium (Mg), zinc (Zn), cadmium (Cd), beryllium (Be), and calcium (Ca), and at least one of these is added as the p-type impurity. The semiconductor layer may have a multilayer structure, for example, including two or more layers which are different in terms of composition, content of the p-type impurity, or the like.

The term “base” indicates a surface of the substrate when the gallium nitride compound semiconductor is formed directly on the surface of the substrate and indicates a surface of a low-temperature growth buffer layer when the gallium nitride compound semiconductor is formed on the surface of the low-temperature growth buffer layer provided on the substrate. Furthermore, when the gallium nitride compound semiconductor layer is one of the semiconductor layers constituting a gallium nitride compound semiconductor device, the base indicates a surface of a semiconductor layer directly beneath the gallium nitride compound semiconductor layer.

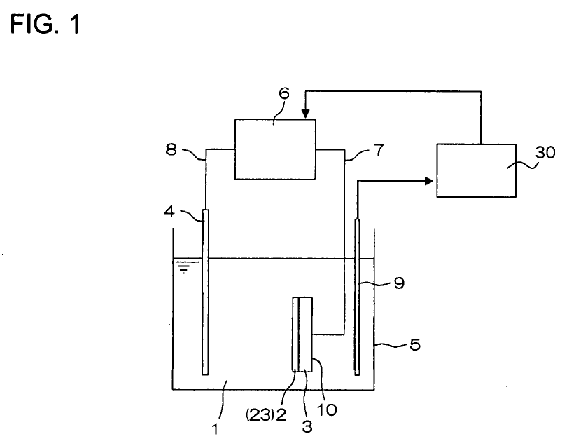

FIG. 1 is a schematic diagram showing an example of a treatment apparatus used in the step of activating the p-type impurity contained in the gallium nitride compound semiconductor in the method for manufacturing the p-type gallium nitride compound semiconductor according to the embodiment of the present invention. Referring to FIG. 1, the treatment apparatus includes an electrolytic tank 5 containing an electrolytic solution 1 in which a conductive substrate 3 provided with a gallium nitride compound semiconductor 2 and a cathode 4 are immersed, a power supply (electric power source) 6 for applying a current between the conductive substrate 3 serving as an anode and the cathode 4, a wire 7 for connecting the power supply 6 to the conductive substrate 3, a wire 8 for connecting the power supply 6 to the cathode 4, and a thermocouple 9 for monitoring the temperature of the electrolytic solution 1 in the electrolytic tank 5. The thermocouple 9 detects the temperature of the conductive substrate 3 indirectly. The thermocouple 9 outputs detection results to a control unit 30, and the control unit 30 controls the power supply 6 on the basis of the detection results.

In the treatment apparatus, the wire 7 is connected to a surface 10 of the conductive substrate 3 opposite to the surface provided with the gallium nitride compound semiconductor 2, for example, with solder, gallium (Ga), indium (In), or the like. Thus, when the wire 7 is bonded to the conductive substrate 3, it is possible to prevent the gallium nitride compound semiconductor 2 from being contaminated with the solder or the like, and the quality of the resulting p-type gallium nitride compound semiconductor can be further enhanced.

As the electrolytic solution 1, for example, water is used. Other examples of the electrolytic solution 1 include aqueous solutions of chlorides, such as an aqueous solution of lithium chloride, an aqueous solution of sodium chloride, and an aqueous solution of potassium chloride; and aqueous solutions of alkali hydroxides, such as an aqueous solution of sodium hydroxide and an aqueous solution of lithium hydroxide. As the cathode 4, a cathode composed of any of various materials that are not dissolved in the electrolytic solution 1 can be used. For example, the cathode 4 is preferably composed of platinum (Pt). As the power supply 6, for example, a constant-current power supply is used.

In a process of performing activation treatment using the treatment apparatus, the conductive substrate 3 and the cathode 4, which are connected to the power supply 6 through the wires 7 and 8, respectively, and the thermocouple 9 are immersed in the electrolytic solution 1 contained in the electrolytic tank 5, and in that state, a current is applied from the power supply 6 between the conductive substrate 3 serving as an anode and the cathode 4. As a result, by means of the mechanism which will be described below, the p-type impurity in the gallium nitride compound semiconductor 2 on the conductive substrate 3 is activated by dehydrogenation, and thus a p-type gallium nitride compound semiconductor is produced.

In this process, preferably, the temperature of the electrolytic solution 1 is monitored with the thermocouple 9 and the value of the current applied between the electrodes is controlled such that the temperature of the conductive substrate 3 calculated from the value measured by the thermocouple 9 does not exceed the melting point of the solder or the like. The controller 30 may control the temperature of the conductive substrate 3 to be a predetermined target temperature. Furthermore, although not shown in the drawing, the electrolytic solution 1 may be designed to be cooled from outside the electrolytic tank 5.

The current value depends on the composition and the thickness of the gallium nitride compound semiconductor 2, the type and the amount of addition of the p-type impurity and cannot be generally specified. As described above, when the activation treatment is performed, preferably, the current value is adjusted to be within the range that allows the temperature of the conductive substrate 3 not to exceed the melting point of the solder or the like, and the current application time is set so that substantially all of the amount of the p-type impurity added to the gallium nitride compound semiconductor 2 can be dehydrogenated.

In the manufacturing method according to the embodiment of the present invention, in an electrolytic solution, a current is applied between a conductive substrate provided with a gallium nitride compound semiconductor used as an anode and a cathode disposed in contact with the electrolytic solution, and thus a p-type impurity in the semiconductor can be activated by dehydrogenation.

That is, when a current is applied between the conductive substrate as the anode and the cathode, electrons (e⁻) are supplied from the electrolyte in the electrolytic solution to the gallium nitride compound semiconductor on the conductive substrate, and bonding between the p-type impurity and hydrogen is broken by the electrons supplied to generate hydrogen ions (H⁺). The resulting hydrogen ions are released from the semiconductor due to the potential difference from the cathode to decrease the hydrogen ion concentration in the semiconductor. Thus, the p-type impurity is believed to be dehydrogenated. The hydrogen ions released from the semiconductor are transported to the cathode, and the electrons are accepted by the surface of the cathode to produce hydrogen molecules (H₂).

Furthermore, when the electrolytic solution contains hydroxyl ions (OH⁻), the hydroxyl ions are attracted by the surface of the gallium nitride compound semiconductor, and electrons are released at the surface and bond with hydrogen ions in the semiconductor to produce water molecules (H₂O). As a result, the hydrogen ion concentration in the semiconductor is decreased. Thus, the p-type impurity is believed to be dehydrogenated.

Furthermore, in the manufacturing method according to the embodiment of the present invention, at least a direct-current power supply for applying a direct current between the conductive substrate and the cathode and an electrolytic tank are required to perform the activation treatment, and the activation treatment can be performed at normal pressures and moreover at relatively low temperatures below the boiling point of the electrolytic solution. Therefore, it is possible to reduce the initial cost and running cost of the treatment apparatus. Furthermore, by placing many conductive substrates at equal distances from a cathode in an electrolytic solution, many gallium nitride compound semiconductor layers on conductive substrates can be subjected to activation treatment at one time, without variations, substantially uniformly.

Furthermore, since the activation treatment is performed in the electrolytic solution and an increase in the temperature of the gallium nitride compound semiconductor is prevented during the activation treatment, the composition of the semiconductor is not varied by the release of nitrogen or the like. Since the metal ions contained in the electrolyte are cations and are attracted toward the cathode during the activation treatment, the semiconductor is not contaminated with the electrolyte, etc. contained in the electrolytic solution. In addition, gallium nitride compound semiconductors, such as gallium nitride, aluminum gallium nitride, and indium gallium nitride, are usually difficult to wet-etch, and therefore, they are not etched by the electrolytic solution used in the activation treatment. Consequently, in the manufacturing method according to the embodiment of the present invention, it is possible to prevent the gallium nitride compound semiconductor from being damaged during the activation treatment.

The activation treatment is performed in a state in which the electrolytic solution is in contact with the entire surface of the gallium nitride compound semiconductor. Consequently, for example, even if the semiconductor is formed into a thin film on a substrate and swelling, warpage, irregularities, or the like occur in a multilayer structure including the substrate and the semiconductor thin film, it is possible to activate the p-type impurity in the semiconductor uniformly without variations in the degree of activation of the p-type impurity and without damaging the multilayer structure.

Consequently, in the manufacturing method according to the embodiment of the present invention, because of the linkage of the various effects described above, it is possible to efficiently produce a p-type gallium nitride compound semiconductor in large quantities in which a substantially constant quality is obtained by efficiently and uniformly activating the gallium nitride compound semiconductor containing the p-type impurity without changing the composition and without the occurrence of contamination or the like. Therefore, it is possible to reduce the manufacturing cost of the p-type gallium nitride compound semiconductor.

In the manufacturing method according to the embodiment of the present invention, when a gallium nitride compound semiconductor containing a p-type impurity is formed by a vapor-phase deposition method on a conductive substrate composed of a single crystal of zirconium diboride (ZrB₂), the lattice constant of which matches that of the gallium nitride compound semiconductor containing the p-type impurity, it is possible to improve the crystal quality. Therefore, the quality of the p-type gallium nitride compound semiconductor manufactured through the activation step can be further enhanced.

Furthermore, when a wire from the power supply is connected to a surface of a conductive substrate other than the surface provided with a gallium nitride compound semiconductor with solder or the like, it is possible to prevent the semiconductor from being contaminated with the solder or the like during bonding to the conductive substrate with the solder or the like, and the quality of the resulting p-type gallium nitride compound semiconductor can be further enhanced.

Furthermore, a gallium nitride compound semiconductor device of the present invention includes the p-type gallium nitride compound semiconductor according to the embodiment of the present invention. Therefore, excellent characteristics, for example, brightness and the like in the case of a light-emitting diode, can be achieved.

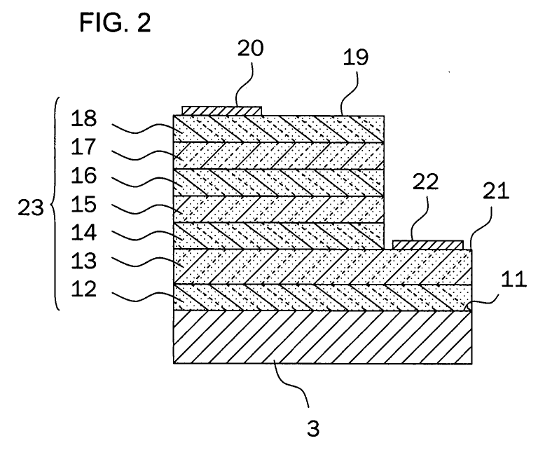

FIG. 2 is a cross-sectional view showing a layer structure of a light-emitting diode as an example of a gallium nitride compound semiconductor device according to an embodiment of the present invention.

Referring to FIG. 2, the light-emitting diode includes a low-temperature growth buffer layer 12, an n-type gallium nitride compound semiconductor 13, an intermediate layer 14, an active region 15, a first p-type gallium nitride compound semiconductor layer 16, a second p-type gallium nitride compound semiconductor layer 17, and a third p-type gallium nitride compound semiconductor layer 18 disposed in that order on a surface 11 of a conductive substrate 3. An electrode pad 20 is disposed on a part of a surface 19 which is perpendicular to the lamination direction of the third p-type gallium nitride compound semiconductor layer 18. A surface 21 which is perpendicular to the lamination direction of the n-type gallium nitride compound semiconductor layer 13 is partially exposed by removing parts of the intermediate layer 14, the active region 15, the first p-type gallium nitride compound semiconductor layer 16, the second p-type gallium nitride compound semiconductor layer 17, and the third p-type gallium nitride compound semiconductor layer 18, and an electrode pad 22 is disposed on the exposed surface 21.

As the low-temperature growth buffer layer 12, for example, a layer composed of gallium nitride (GaN), aluminum nitride (AlN), or the like is used. An example of the n-type gallium nitride compound semiconductor layer 13 is a layer composed of gallium nitride (GaN) containing silicon (Si) as an n-type impurity. The intermediate layer 14 is a layer for enhancing the crystal quality of the active region 15, and an example of the intermediate layer 14 is a layer composed of indium gallium nitride (InₓGa₁₋ₓN).

An example of the active region 15 is a multiple-quantum-well (MQW) layer, which is a superlattice device, in which, for example, barrier layers composed of gallium nitride (GaN) and well layers composed of indium gallium nitride (InₓGa₁₋ₓN) are alternately stacked, or barrier layers and well layers composed of indium gallium nitride (InₓGa₁₋ₓN), the barrier layers and the well layers having different composition x, are alternately stacked, such that a barrier layer is disposed as each of the top layer and the bottom layer of the laminate.

As each of the first and second p-type gallium nitride compound semiconductor layers 16 and 17, for example, a layer composed of aluminum gallium nitride (AlₓGa₁₋ₓN) to which magnesium (Mg) or the like is added as a p-type impurity, the p-type impurity being activated by the manufacturing method according to the embodiment of the present invention, is used. As the third p-type gallium nitride compound semiconductor layer 18, for example, a layer composed of gallium nitride (GaN) to which magnesium (Mg) or the like is added as a p-type impurity, the p-type impurity being activated by the manufacturing method according to the embodiment of the present invention, is used.

An example of the electrode pad 20 is a laminate including a nickel (Ni) layer disposed on the surface 19 of the third p-type gallium nitride compound semiconductor 18 and a gold (Au) layer disposed on the nickel layer. An example of the electrode pad 22 is a laminate including a titanium (Ti) layer, an aluminum (Al) layer, a nickel layer, and a gold layer disposed in that order on the exposed surface 21 of the n-type gallium nitride compound semiconductor layer 13.

The individual layers from the low-temperature growth buffer layer 12 to the layer of a gallium nitride compound semiconductor containing a p-type impurity, which eventually becomes the third p-type gallium nitride compound semiconductor layer 18, are formed, for example, by the vapor-phase deposition method, such as MOCVD, which is described above. That is, a conductive substrate 3 is placed in a chamber of an apparatus for carrying out MOCVD, and while maintaining the conductive substrate 3 at a temperature suitable for the growth of each layer, source gases for forming each layer are introduced to allow chemical reactions to occur on the base, which is described above, so that a gallium nitride compound having a predetermined composition is deposited on the base. This operation is repeated for each layer. A laminate 23 including the individual layers is thus formed.

Examples of the source gas for gallium, which is introduced into the chamber, include trimethylgallium [Ga(CH₃)₃]. Examples of the source gas for nitrogen include ammonia (NH₃). Examples of the source gas for magnesium include biscyclopentadienyl magnesium [(C₅H₅)₂Mg].

Referring to FIG. 1, after the laminate 23 is formed, the wire 7 from the power supply 6 is connected to the surface 10 of the conductive substrate 3 opposite to the surface provided with the laminate 23, and the activation treatment is performed. As a result, in each of the three gallium nitride compound semiconductor layers containing a p-type impurity, which constitute the laminate 23 and which eventually become the first to third p-type gallium nitride compound semiconductor layers 16 to 18, the p-type impurity is activated by dehydrogenation by means of the mechanism described above. Thus, the first p-type gallium nitride compound semiconductor layer 16, the second p-type gallium nitride compound semiconductor layer 17, and the third p-type gallium nitride compound semiconductor layer 18 are formed.

Subsequently, for example, by combining photolithography and dry or wet etching, parts of the intermediate layer 14, the active region 15, the first p-type gallium nitride compound semiconductor layer 16, the second p-type gallium nitride compound semiconductor layer 17, and the third p-type gallium nitride compound semiconductor layer 18 are removed to partially expose the surface 21 of the n-type gallium nitride compound semiconductor layer 13. Then, by combining photolithography, evaporation method, and a lift-off technique or the like, the electrodes pads 20 and 22 are formed on the surface of the third p-type gallium nitride compound semiconductor layer 18 and the exposed surface 21 of the n-type gallium nitride compound semiconductor layer 13. The light-emitting diode shown in FIG. 2 is thereby produced.

In practice, a conductive substrate 3 (wafer) that is sufficiently large for supporting a plurality of light-emitting devices is used, and a plurality of light-emitting devices is manufactured by the following procedure. That is, a laminate 23 is formed on the surface of the wafer-like conductive substrate 3, and in three gallium nitride compound semiconductor layers containing a p-type impurity, which constitute the laminate 23 and which eventually become first to third p-type gallium nitride compound semiconductor layers 16 to 18, the p-type impurity is activated by dehydrogenation by the manufacturing method according to the embodiment of the present invention. Thus, the first to third p-type gallium nitride compound semiconductor layers 16 to 18 are formed.

Subsequently, in each of the light-emitting device regions, predetermined parts of the intermediate layer 14, the active region 15, the first p-type gallium nitride compound semiconductor layer 16, the second p-type gallium nitride compound semiconductor layer 17, and the third p-type gallium nitride compound semiconductor layer 18 are removed to partially expose the surface 21 of the n-type gallium nitride compound semiconductor layer 13, and electrodes pads 20 and 22 are formed on the surface 19 of the third p-type gallium nitride compound semiconductor layer 18 and the exposed surface 21 of the n-type gallium nitride compound semiconductor layer 13. Then, the individual regions are separated by cutting. Thus, a plurality of light-emitting devices is produced.

In the light-emitting device, when a current is applied between the electrode pads 20 and 22, the holes injected from the electrode pad 20 into the third p-type gallium nitride compound semiconductor layer 18 are transported through the third p-type gallium nitride compound semiconductor layer 18, the second p-type gallium nitride compound semiconductor layer 17, and the first p-type gallium nitride compound semiconductor layer 16 toward the conductive substrate 3, and the electrons injected from the electrode pads 22 into the n-type gallium nitride compound semiconductor layer 13 are transported through the n-type gallium nitride compound semiconductor layer 13 and the intermediate layer 14 toward the electrode pads 20. Thereby, the holes and the electrons are recombined in the active region 15, and as a result, the gallium nitride compound constituting the active region 15 is excited to emit light.

The present invention is not limited to the examples described above with reference to the drawings. It is to be understood that various modifications could be made without departing from the spirit of the invention. For example, according to the embodiment of the present invention, as described above, many conductive substrates 3 may be immersed in the electrolytic solution 1 so that gallium nitride compound semiconductor layers 2 on the many conductive substrates 3 are subjected to activation treatment at one time. In such a case, in order to avoid variations in the activation treatment, the individual conductive substrates 3 may be placed at equal distances from a cathode 4. Alternatively, a cathode 4 may be prepared for each conductive substrate 3 and the individual cathodes 4 may be placed at equal distances from the corresponding conductive substrates 3. Furthermore, at least the inner surface of the electrolytic tank 5 may be composed of a conductive material and connected to the power supply 6, and thus the cathode 4 may be omitted.

The p-type gallium nitride compound semiconductor manufactured by the manufacturing method according to the embodiment of the present invention may be incorporated into gallium nitride compound semiconductor devices other than light-emitting devices.

The gallium nitride compound semiconductor devices of the present invention can be applied to light-receiving devices, such as photodetectors and flame sensors; and electron devices, such as field effect transistors (FETs), metal-semiconductor FETs (MESFETs), metal-insulator-semiconductor FETs (MISFETs), and high electron mobility transistors (HEMTs).

### EXAMPLE 1

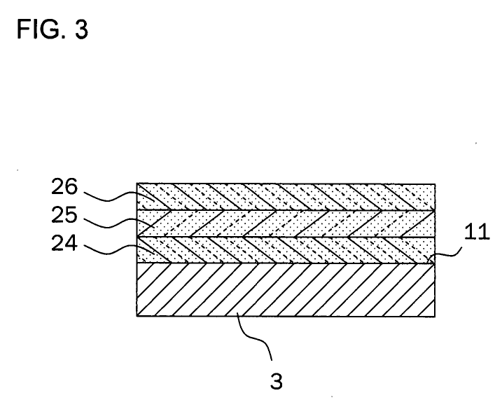

In order to confirm that a p-type impurity in a gallium nitride compound semiconductor can be activated by the manufacturing method according to the embodiment of the present invention, as shown in FIG. 3, a model of a gallium nitride compound semiconductor device was fabricated in which a low-temperature growth buffer layer 24 composed of gallium nitride (GaN), unintentionally doped gallium nitride (GaN) layer 25, and a gallium nitride (GaN) layer 26 containing a p-type impurity were deposited by MOCVD on a surface 11 of a conductive substrate 3 composed of a single crystal of zirconium diboride (ZrB₂).

Specifically, the conductive substrate 3 was placed in a chamber of an apparatus for carrying out MOCVD, the temperature of the conductive substrate 3 was increased to 1,100° C., and the surface 11 was subjected to thermal etching. Then, while maintaining the temperature at 400° C., trimethylgallium [Ga(CH₃)₃] and ammonia (NH₃) were introduced into the chamber to allow a chemical reaction to occur on the surface 11. Thus, a low-temperature growth buffer layer 24 with a thickness of 20 nm was formed.

Subsequently, the temperature of the conductive substrate 3 was increased to 1,050° C., and while maintaining the temperature, trimethylgallium [Ga(CH₃)₃] and ammonia (NH₃) were introduced into the chamber to allow a chemical reaction to occur on the low-temperature growth buffer layer 24. Thus, a gallium nitride layer 25 was formed on the low-temperature growth buffer layer 24. At the point when the thickness of the gallium nitride layer 25 reached 2 μm, biscyclopentadienyl magnesium [(C₅H₅)₂Mg] was further introduced into the chamber to allow a chemical reaction to occur on the gallium nitride layer 25. Thus, a gallium nitride layer 26 containing magnesium as a p-type impurity with a thickness of 1 μm was formed.

Subsequently, referring to FIG. 1, a copper wire as the wire 7 was connected, using gold-tin (Au—Sn) alloy solder, to a surface 10 opposite to the surface 11 of the conductive substrate 3 of the model of the device taken out of the chamber. With the wire 7 connected to the power supply 6 and with the wire 8 connected to a platinum electrode as the cathode 4, the conductive substrate 3, the cathode 4, and the thermocouple 9 were immersed in an aqueous solution of sodium hydroxide as the electrolytic solution 1.

Subsequently, a current was applied from the power supply 6 between the cathode 4 and the conductive substrate 3 as an anode. A current density of 1 mA/mm² was applied for 30 minutes. During the current application, the temperature of the electrolytic solution 1 monitored by the thermocouple 9 was 100° C. or lower. The surface of the gallium nitride layer 26 after treatment was observed with a microscope. The observation showed that the morphology of the surface was not changed from that before the treatment and the gallium nitride layer 26 was not etched by the treatment.

The hole concentration in the outermost gallium nitride layer 26 of the model of the device was measured before and after the treatment. Before the treatment, the hole concentration was low to such an extent that did not permit measurement because of high resistance. After the treatment, the hole concentration had increased to 2×10¹⁸ cm⁻³. Thus, it was confirmed that magnesium as the p-type impurity contained in the gallium nitride layer 26 was activated by dehydrogenation.

### EXAMPLE 2

In Example 2, a light-emitting device having a layer structure shown in FIG. 2 was fabricated. That is, first, a wafer-like conductive substrate 3 that was sufficiently large for supporting a plurality of light-emitting devices was placed in a chamber of an apparatus for carrying out MOCVD, the temperature of the conductive substrate 3 was increased to 1,100° C., and the surface 11 was subjected to thermal etching. Then, while maintaining the temperature at 400° C., trimethylgallium [Ga(CH₃)₃] and ammonia (NH₃) were introduced into the chamber to allow a chemical reaction to occur on the surface 11. Thus, a low-temperature growth buffer layer 12 with a thickness of 20 nm was formed.

Subsequently, the temperature of the conductive substrate 3 was increased to 1,050° C., and while maintaining the temperature, trimethylgallium, ammonia, and silane (SiH₄) as a source for silicon (Si), i.e., an n-type impurity, were introduced into the chamber to allow a chemical reaction to occur on the low-temperature growth buffer layer 12. Thus, a gallium nitride (GaN) layer containing silicon (Si) as the n-type gallium nitride compound semiconductor layer 13 was formed on the low-temperature growth buffer layer 12. At the point when the thickness of the n-type gallium nitride compound semiconductor layer 13 reached 2 μm, the introduction of silane was terminated, and trimethylindium [In(CH₃)₃] as a source for indium (In) was introduced into the chamber to allow a chemical reaction to occur on the n-type gallium nitride compound semiconductor layer 13. Thus, an indium gallium nitride (InₓGa₁₋ₓN, 0≦x≦0.2) layer as the intermediate layer 14 with a thickness of 0.5 μm was formed on the n-type gallium nitride compound semiconductor layer 13.

Subsequently, while maintaining the temperature of the conductive substrate 3 at 750° C., trimethylgallium and ammonia were continuously introduced into the chamber and also trimethylindium was intermittently introduced into the chamber to allow chemical reactions to occur on the intermediate layer 14. Thus, a multiple-quantum-well (MQW) layer, i.e., a superlattice device, was fabricated as the active region 15, in which barrier layers composed of gallium nitride (GaN) and well layers composed of (InₓGa₁₋ₓN, 0≦x≦0.2) were alternately stacked and a barrier layer was disposed as each of the top layer and the bottom layer thereof.

Subsequently, while maintaining the temperature of the conductive substrate 3 at 750° C., trimethylgallium, ammonia, trimethylaluminum [Al(CH₃)₃] as a source for aluminum (Al), and biscyclopentadienyl magnesium [(C₅H₅)₂Mg] as a source for magnesium (Mg), i.e., a p-type impurity, were introduced into the chamber to allow a chemical reaction to occur on the active region 15. Thus, an aluminum gallium nitride (Al_{0.2}Ga_{0.8}N) layer containing magnesium as the p-type impurity, which eventually became the first p-type gallium nitride compound semiconductor layer 16, with a thickness of 20 nm was formed.

Subsequently, with the same gases as those described above being introduced, the temperature of the conductive substrate 3 was increased to 850° C., and a chemical reaction was allowed to occur on the aluminum gallium nitride layer. Thus, an aluminum gallium nitride (Al_{0.1}Ga_{0.9}N) layer containing magnesium as the p-type impurity, which eventually became the second p-type gallium nitride compound semiconductor layer 17, with a thickness of 200 nm was formed.

Lastly, while maintaining the temperature of the conductive substrate 3 at 850° C., trimethylgallium, ammonia, and biscyclopentadienyl magnesium were introduced into the chamber, and a chemical reaction was allowed to occur on the aluminum gallium nitride layer. Thus, a gallium nitride (GaN) layer containing magnesium as the p-type impurity, which eventually became the third p-type gallium nitride compound semiconductor layer 18, with a thickness of 20 nm was formed, and thereby, a laminate 23 was produced.

Subsequently, referring to FIG. 1, a copper wire as the wire 7 was connected, using gold-tin (Au—Sn) alloy solder, to a surface 10 opposite to the surface 11 of the conductive substrate 3 taken out of the chamber. With the wire 7 connected to the power supply 6 and with the wire 8, which was connected to a platinum electrode as the cathode 4, also connected to the power supply 6, the conductive substrate 3, the cathode 4, and the thermocouple 9 were immersed in an aqueous solution of sodium hydroxide as the electrolytic solution 1.

In the immersion state, a current was applied from the power supply 6 between the cathode 4 and the conductive substrate 3 as an anode. A current density of 1 mA/mm² was applied for 30 minutes. During the current application, the temperature of the electrolytic solution 1 monitored by the thermocouple 9 did not substantially increase. The surface of the gallium nitride layer at the outermost surface of the laminate 23 after treatment was observed with a microscope. The observation showed that the morphology of the surface was not changed from that before the treatment and the gallium nitride layer was not etched by the treatment.

Subsequently, in each of the light-emitting device regions, predetermined parts of the intermediate layer 14, the active region 15, the first p-type gallium nitride compound semiconductor layer 16, the second p-type gallium nitride compound semiconductor layer 17, and the third p-type gallium nitride compound semiconductor layer 18 were removed to partially expose the surface 21 of the n-type gallium nitride compound semiconductor layer 13. Then, an electrode pad 20 having a multilayer structure including a nickel (Ni) layer and a gold (Au) layer was formed on the surface of the third p-type gallium nitride compound semiconductor layer 18, and an electrode pad 22 having a multilayer structure including a titanium (Ti) layer, an aluminum (Al) layer, a nickel layer, and a gold layer was formed on the exposed surface 21 of the n-type gallium nitride compound semiconductor layer 13. Then, the individual regions were separated by cutting. Thus, a plurality of light-emitting devices was produced.

A current was applied in the forward direction between the electrode pads 20 and 22 of the light-emitting device, and the current-voltage characteristics were measured. The operating voltage at a current of 20 mA was 3.5 V. This operating voltage was equivalent to that in the case in which the three gallium nitride compound semiconductor layers containing the p-type impurity were annealed at 400° C. for 10 minutes to perform activation by dehydrogenation. In both cases, the luminescence intensity was also substantially the same.

Obviously, numerous modifications and variations of the present invention are possible in light of the above teachings. It is therefore to be understood that within the scope of the appended claims, the invention may be practiced otherwise than as specifically described herein.

What is claimed as new and is desired to be secured by Letters Patent of the United States is:

1. A method for manufacturing a p-type gallium nitride compound semiconductor, comprising:
providing a gallium nitride compound semiconductor containing a p-type impurity on a conductive substrate;
immersing in an electrolytic solution the conductive substrate on which the gallium nitride compound semiconductor is provided;
providing a cathode to be in contact with the electrolytic solution; and
applying a current between the cathode and the conductive substrate serving as an anode to activate the p-type impurity.

2. The method for manufacturing a p-type gallium nitride compound semiconductor according to claim 1, wherein the conductive substrate has a resistivity of about 10⁻¹ to 10⁻⁶ Ωcm.

3. The method for manufacturing a p-type gallium nitride compound semiconductor according to claim 1, wherein the conductive substrate comprises gallium oxide, silicon carbide, gallium nitride, zirconium diboride, or titanium diboride.

4. The method for manufacturing a p-type gallium nitride compound semiconductor according to claim 1, wherein the conductive substrate comprises a single crystal of zirconium diboride.

5. The method for manufacturing a p-type gallium nitride compound semiconductor according to claim 1, wherein the p-type impurity includes at least one of magnesium, zinc, cadmium, beryllium, and calcium.

6. The method for manufacturing a p-type gallium nitride compound semiconductor according to claim 1, wherein the conductive substrate comprises a single crystal of zirconium diboride, and wherein the gallium nitride compound semiconductor containing the p-type impurity is provided on the conductive substrate using a vapor-phase deposition method.

7. The method for manufacturing a p-type gallium nitride compound semiconductor according to claim 6, wherein the vapor-phase deposition method is a metalorganic chemical vapor deposition method.

8. The method for manufacturing a p-type gallium nitride compound semiconductor according to claim 1, wherein another surface of the conductive substrate other than a surface on which the gallium nitride compound semiconductor is provided is connected to an electric power source.

9. The method for manufacturing a p-type gallium nitride compound semiconductor according to claim 8, wherein said another surface of the conductive substrate is an opposite surface opposite to the surface on which the gallium nitride compound semiconductor is provided.

10. The method for manufacturing a p-type gallium nitride compound semiconductor according to claim 1, wherein an electrolytic container contains the electrolytic solution and has an inner surface which is made of a conductive material and is used as the cathode.

11. The method for manufacturing a p-type gallium nitride compound semiconductor according to claim 1, wherein the gallium nitride compound semiconductor is made from gallium nitride, aluminum gallium nitride, or indium gallium nitride.

12. The method for manufacturing a p-type gallium nitride compound semiconductor according to claim 1, wherein the electrolytic solution includes water; aqueous solutions of chlorides including an aqueous solution of lithium chloride, an aqueous solution of sodium chloride, or an aqueous solution of potassium chloride; or aqueous solutions of alkali hydroxides including an aqueous solution of sodium hydroxide or an aqueous solution of lithium hydroxide.

13. The method for manufacturing a p-type gallium nitride compound semiconductor according to claim 1, wherein the cathode is made of platinum.

14. A gallium nitride compound semiconductor device comprising:
a p-type gallium nitride compound semiconductor manufactured by the method according to claim 1.

15. A method for activating a p-type impurity contained in a gallium nitride compound semiconductor, the method comprising:
immersing in an electrolytic solution a conductive substrate on which the gallium nitride compound semiconductor containing the p-type impurity is provided;
providing a cathode to be in contact with the electrolytic solution; and
applying a current between the cathode and the conductive substrate serving as an anode immersed in the electrolytic solution to activate the p-type impurity.

16. An apparatus for activating a p-type impurity contained in a gallium nitride compound semiconductor, said apparatus comprising:
a container configured to contain an electrolytic solution;
a cathode provided in the container to be in contact with the electrolytic solution;
an anode comprising a conductive substrate on which a gallium nitride compound semiconductor containing a p-type impurity is provided and which is to be in contact with the electrolytic solution;
an electric power source configured to apply a current between the anode and the cathode; and
a controller configured to control the electric power source to activate the p-type impurity.

17. The apparatus according to claim 16, further comprising:
a temperature sensor configured to detect a temperature of the anode, wherein the controller is configured to control the temperature of the anode to be a predetermined target temperature.
